(19) United States
(12) Patent Application Publication
(10) Pub. No.: US 2007/0049020 A1
(43) Pub. Date: Mar. 1, 2007

(54) Method and apparatus for reducing tensile stress in a deposited layer

(75) Inventors: Yi-Chiau Huang, Fremont, CA (US); Bo Zheng, Saratoga, CA (US); Lei Zhu, Sunnyvale, CA (US); Christopher R. McGuirk, San Jose, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/214,289

(22) Filed: Aug. 29, 2005

(51) Int. Cl. H01L 21/44

(52) U.S. Cl. 438/680

(57) ABSTRACT

A method and apparatus for compensating for tensile stress on a layer deposited on a substrate. The method includes disposing the substrate between a bladder and a contact ring, and applying pressure against a back side of the substrate toward the contact ring to bend a center region of the substrate until the substrate assumes a convex shape relative to an upward flow of a plating solution.

### BACKGROUND OF THE INVENTION

1. Field of the Invention

Embodiments of the invention generally relate to a system for annealing semiconductor substrates.

2. Description of the Related Art

Metallization of sub-quarter micron sized features is a foundational technology for present and future generations of integrated circuit manufacturing processes. More particularly, in devices such as ultra large scale integration-type devices, i.e., devices having integrated circuits with more than a million logic gates, the multilevel interconnects that lie at the heart of these devices are generally formed by filling high aspect ratio, i.e., greater than about 4:1, interconnect features with a conductive material, such as copper. Conventionally, deposition techniques such as chemical vapor deposition (CVD) and physical vapor deposition (PVD) have been used to fill these interconnect features. However, as the interconnect sizes decrease and aspect ratios increase, void-free interconnect feature fill via conventional metallization techniques becomes increasingly difficult. Therefore, plating techniques, i.e., electrochemical plating (ECP) and electroless plating, have emerged as promising processes for void free filling of sub-quarter micron sized high aspect ratio interconnect features in integrated circuit manufacturing processes.

In an ECP process, for example, sub-quarter micron sized high aspect ratio features formed into the surface of a substrate (or a layer deposited thereon) may be efficiently filled with a conductive material. ECP plating processes are generally two stage processes, wherein a seed layer is first formed over the surface features of the substrate (generally through PVD, CVD, or other deposition process in a separate tool), and then the surface features of the substrate are exposed to an electrolyte solution (in the ECP tool), while an electrical bias is applied between the seed layer and a copper anode positioned within the electrolyte solution. The electrolyte solution generally contains ions to be plated onto the surface of the substrate, and therefore, the application of the electrical bias causes these ions to be plated onto the biased seed layer, thus depositing a layer of the ions on the substrate surface that may fill the features.

Once the plating process is completed, the substrate is generally transferred to at least one of a substrate rinsing cell or a bevel edge clean cell. Bevel edge clean cells are generally configured to dispense an etchant onto the perimeter or bevel of the substrate to remove unwanted metal plated thereon. The substrate rinse cells, often called spin rinse dry cells, generally operate to rinse the surface of the substrate (both front and back) with a rinsing solution to remove any contaminants therefrom. Further, the rinse cells are often configured to spin the substrate at a high rate of speed in order to spin off any remaining fluid droplets adhering to the substrate surface. Once the remaining fluid droplets are spun off, the substrate is generally clean and dry, and therefore, ready for transfer from the ECP tool.

To overcome problems associated with void formation as well as variation in copper oxidation, heat treatment of a film after deposition is generally performed. One effective technique for heat treating the film is annealing. Annealing is the process of subjecting a material to heat for a specific period of time. Annealing may also provide a thermodynamic driving force for the metal layers to form a predictable microstructure. A metal layer can, for example, be annealed in a particular atmosphere in order to provide a specific and predictable set of electrical properties (e.g. electrical resistivity).

Since copper has a relatively low melting temperature compared to other metals typically deposited in semiconductor manufacturing, copper is a promising candidate for annealing. New developments in semiconductor manufacturing that have focused on depositing copper, especially by ECP techniques, have sparked new interest in developing improved copper annealing processes. Additionally, copper deposited by ECP undergoes the physical phenomena of self-annealing. In self-annealing, copper undergoes microstructural changes after plating at room temperature. High temperature annealing can modify this self-annealing process.

In conventional annealing processes, substrates may be typically heated to temperatures from about 250° C. to 450° C. for about 45 seconds to about 30 minutes. However, due to the recrystallization or densification of the ECP deposited layer during the annealing process and perhaps, thermal expansion mismatch between the substrate and the ECP deposited layer, the ECP deposited layer often experiences a tensile stress after the annealing process. Depending on the extent of the stress, tensile stress often reduces the quality of the deposited layer.

Some have tried to reduce the extent of the tensile stress by varying plating bath compositions. However, varying the plating bath compositions often leads to a change in layer resistivity.

Accordingly, a need exists in the art for a new method and apparatus for reducing or compensating for the tensile stress experienced by the deposited layer during annealing.

### SUMMARY OF THE INVENTION

Various embodiments of the invention are directed to a method for compensating for tensile stress on a layer deposited on a substrate. The method includes disposing the substrate between a bladder and a contact ring, and applying pressure against a back side of the substrate toward the contact ring to bend a center region of the substrate until the substrate assumes a convex shape relative to an upward flow of a plating solution.

Various embodiments of the invention are also directed to a method for compensating for tensile stress on a film deposited on a substrate. The method includes providing a thrust plate having a bottom surface defining a first circular recess for containing a first o-ring and a second circular recess for containing a second o-ring. The diameter of the first o-ring is substantially larger than the diameter of the second o-ring and the diameter of the first o-ring substantially coincides with the diameter of the substrate. The method further includes disposing the substrate between the thrust plate and a contact ring and applying pressure against a back side of the substrate toward the contact ring to bend a center region of the substrate.

Various embodiments of the invention are also directed to thrust plate for retaining a substrate. The thrust plate includes a first o-ring for biasing a back side of the substrate against a contact ring. The first o-ring has a diameter substantially the same as the diameter of the substrate and a second o-ring for bending a center region of the substrate. The second o-ring has a diameter less than the first o-ring.

Various embodiments of the invention are also directed a method for annealing a substrate. The method includes positioning the substrate on a heating plate for a first predetermined period of time. The heating plate comprises a curved substrate support surface and the heating plate is maintained at a temperature of between about 200° C. and 400° C. The method further includes pressing the substrate against the curved substrate support surface.

Various embodiments of the invention are also directed an annealing chamber, which includes a heating plate having a first curved substrate support surface, a cooling plate having a second curved substrate support surface and a substrate transfer mechanism configured to transfer one or more substrates between the heating plate and the cooling plate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top plan view of an electrochemical plating system that may include one or more embodiments of the invention.

FIG. 2 illustrates a plating cell that may be used in the electrochemical plating system of FIG. 1.

FIG. 3A illustrates an enlarged cross sectional view of a thrust plate in accordance with one or more embodiments of the invention.

FIG. 3B illustrates a bladder inflatable assembly that may be used in connection with one or more embodiments of the invention.

FIG. 3C illustrates an expanded cross sectional view of a bladder area of the bladder inflatable assembly of FIG. 3B.

FIG. 4 illustrates a perspective view of an annealing system in accordance with one or more embodiments of the invention.

FIG. 5 illustrates a top perspective view of an annealing chamber 500 in accordance with one or more embodiments of the invention.

FIG. 6 illustrates a cross sectional view of a heating plate in accordance with one or more embodiments of the invention.

### DETAILED DESCRIPTION OF THE PREFERRED EMBODIMENT

Embodiments of the invention provide a method and apparatus that can be used to reduce the tensile stress developed in a layer of film deposited by electrochemical plating (ECP). The method and apparatus generally provide ways to bend or bow a substrate during one of the ECP deposition processing steps (e.g., ECP deposition, anneal process) to compensate for the tensile stress induced in the ECP deposited film after the annealing process. Although the various to bend or bow the substrate are described with reference to an ECP process, other embodiments contemplate the various ways of bending the substrate in an electroless deposition processing system.

The term “substrate” as used herein may refer to any monolithic or multi-layer structure upon which a film forming process may be performed. Materials commonly used in the semiconductor industry to form substrates may include monocrystalline silicon (e.g., Si<100>, Si<111>), polycrystalline silicon, amorphous silicon, strained silicon, silicon on insulator (SOI), doped silicon, silicon germanium, germanium, gallium arsenide, glass, sapphire, silicon oxide, silicon carbon nitride, silicon nitride, silicon oxynitride and/or carbon doped silicon oxides, such as SiOₓC_{y}, for example, BLACK DIAMOND™ low-k dielectric, available from Applied Materials, Inc., located in Santa Clara, Calif. Substrates may have various dimensions, such as 200 mm or 300 mm diameter wafers, as well as rectangular or square panes. Substrates on which embodiments of the invention may be useful include, but are not limited to semiconductor wafers, such as monocrystalline silicon, silicon oxide, strained silicon, silicon germanium, doped or undoped polysilicon, doped or undoped silicon wafers, and patterned or non-patterned wafers. Substrates made of glass or plastic, which are commonly used to fabricate flat panel displays and other similar devices, may also be included.

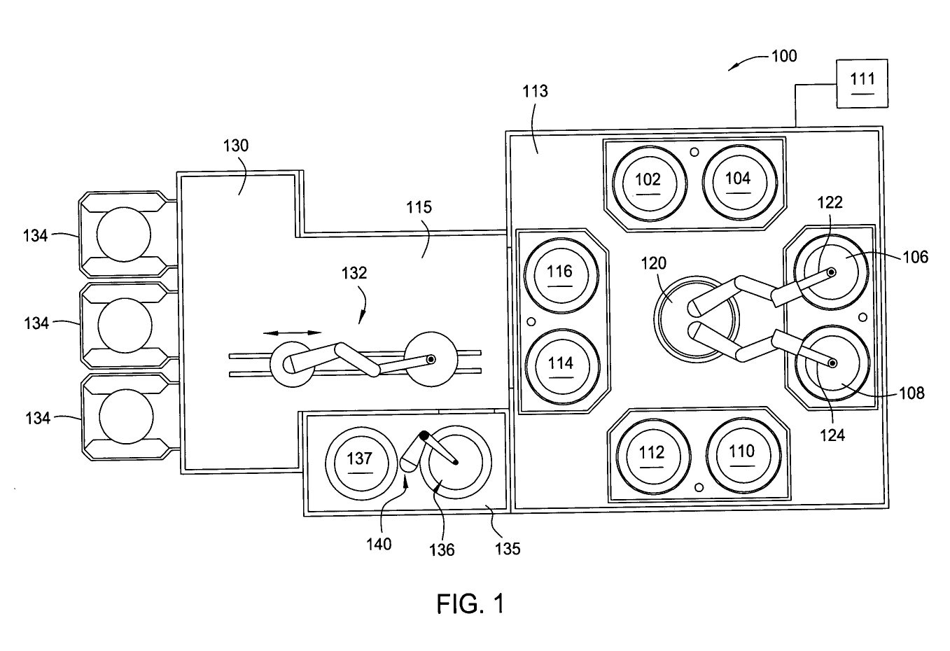

FIG. 1 illustrates a top plan view of an exemplary ECP system 100 that may include one or more embodiments of the invention. ECP system 100 includes a factory interface (FI) 130, which may also be termed a substrate loading station. Factory interface 130 includes a plurality of substrate loading stations configured to interface with substrate containing cassettes 134. A robot 132 is positioned in factory interface 130 and is configured to access substrates contained in the cassettes 134. Further, robot 132 also extends into a link tunnel 115 that connects factory interface 130 to processing mainframe or platform 113. The position of robot 132 allows the robot to access substrate cassettes 134 to retrieve substrates therefrom and then deliver the substrates to one of the processing cells 114, 116 positioned on the mainframe 113, or alternatively, to the annealing station 135. Similarly, robot 132 may be used to retrieve substrates from the processing cells 114, 116 or the annealing station 135 after a substrate processing sequence is complete. In this situation, robot 132 may deliver the substrate back to one of the cassettes 134 for removal from system 100.

The anneal station 135, which will be discussed further herein, may include a two position annealing chamber, in which a cooling plate/position 136 and a heating plate/position 137 are positioned adjacently with a substrate transfer robot 140 positioned proximate between the two stations. The robot 140 is generally configured to move substrates between the respective heating 137 and cooling plates 136. It should be noted that number of processing positions and the orientation of the anneal chamber as shown herein are not intended to limit the scope of the invention.

As mentioned above, ECP system 100 also includes a processing mainframe 113 having a substrate transfer robot 120 centrally positioned thereon. Robot 120 generally includes one or more arms/blades 122, 124 configured to support and transfer substrates thereon. Additionally, robot 120 and the accompanying blades 122, 124 are generally configured to extend, rotate, and vertically move so that robot 120 may insert and remove substrates to and from a plurality of processing locations 102, 104, 106, 108, 110, 112, 114, 116 positioned on the mainframe 113. Similarly, factory interface robot 132 also includes the ability to rotate, extend, and vertically move its substrate support blade, while also allowing for linear travel along the robot track that extends from the factory interface 130 to the mainframe 113.

Process locations 102, 104, 106, 108, 110, 112, 114, 116 may be any number of processing cells utilized in an electrochemical plating platform. More particularly, the process locations may be configured as electrochemical plating cells, rinsing cells, bevel clean cells, spin rinse dry cells, substrate surface cleaning cells (which collectively includes cleaning, rinsing, and etching cells), electroless plating cells, metrology inspection stations, and/or other processing cells that may be beneficially used in conjunction with a plating platform. Each of the respective processing cells and robots are generally in communication with a process controller 111, which may be a microprocessor-based control system configured to receive inputs from both a user and/or various sensors positioned on the system 100 and appropriately control the operation of system 100 in accordance with the inputs.

In the exemplary plating system illustrated in FIG. 1, the processing locations may be configured as follows. Processing locations 114 and 116 may be configured as an interface between the wet processing stations on the mainframe 113 and the dry processing regions in the link tunnel 115, annealing station 135, and the factory interface 130. The processing cells located at the interface locations may be spin rinse dry cells and/or substrate cleaning cells. Each of locations 114 and 116 may include both a spin rinse dry cell and a substrate cleaning cell in a stacked configuration. Locations 102, 104, 110, and 112 may be configured as plating cells, either electrochemical plating cells or electroless plating cells, for example. Locations 106, 108 may be configured as substrate bevel cleaning cells. Additional configurations and implementations of an electrochemical processing system are illustrated in commonly assigned U.S. patent application Ser. No. 10/438,624 filed on May 14, 2003 entitled “Multi-Chemistry Electrochemical Processing System”, which is incorporated herein by reference in its entirety.

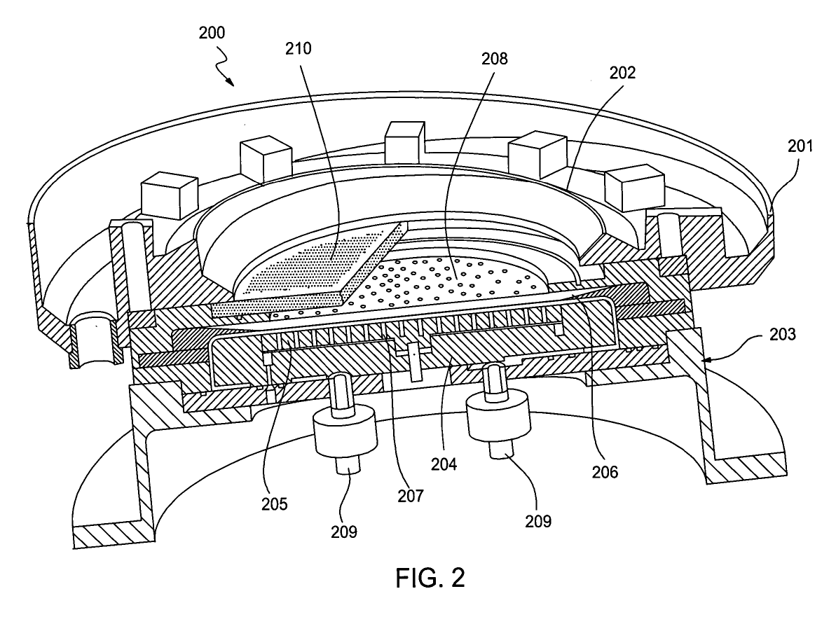

FIG. 2 illustrates a partial perspective view of an electrochemical plating cell 200 that may be implemented in processing locations 102, 104, 110, and 112. The electrochemical plating cell 200 may include an outer basin 201 and an inner basin 202 positioned within outer basin 201. The inner basin 202 is generally configured to contain a plating solution used to plate a metal, e.g., copper, onto a substrate during an electrochemical plating process. During the plating process, the plating solution is generally continuously supplied to inner basin 202 (at about 1 gallon per minute for a 10 liter plating cell, for example), and therefore, the plating solution continually overflows the uppermost point (generally termed a “weir”) of inner basin 202 and is collected by outer basin 201 and drained therefrom for chemical management and recirculation. Plating cell 200 may be positioned at a tilt angle, i.e., the frame member 203 of plating cell 200 may be elevated on one side such that the components of plating cell 200 may be tilted between about 3° and about 30° for optimal results. The frame member 203 of plating cell 200 supports an annular base member on an upper portion thereof. Since frame member 203 is elevated on one side, the upper surface of base member 204 is generally tilted from the horizontal at an angle that corresponds to the angle of frame member 203 relative to a horizontal position. Base member 204 includes an annular or disk shaped recess formed into a central portion thereof, the annular recess being configured to receive a disk shaped anode member 205. Base member 204 further includes a plurality of fluid inlets/drains 209 extending from a lower surface thereof.

Each of the fluid inlets/drains 209 are generally configured to individually supply or drain a fluid to or from either the anode compartment or the cathode compartment of plating cell 200. Anode member 205 generally includes a plurality of slots 207 formed therethrough, wherein the slots 207 are generally positioned in parallel orientation with each other across the surface of the anode 205. The parallel orientation allows for dense fluids generated at the anode surface to flow downwardly across the anode surface and into one of the slots 207.

Plating cell 200 further includes a membrane support assembly 206. Membrane support assembly 206 may be secured at an outer periphery thereof to base member 204, and may include an interior region configured to allow fluids to pass therethrough. A membrane 208 is stretched across the support assembly 206 and operates to fluidly separate a catholyte chamber and anolyte chamber portions of the plating cell. The membrane support assembly 206 may include an o-ring type seal positioned near a perimeter of the membrane, wherein the seal is configured to prevent fluids from traveling from one side of the membrane secured on the membrane support to the other side of the membrane. A diffusion plate 210 is generally positioned in the cell between membrane 208 and the substrate being plated. The diffusion plate 210 may be a porous ceramic disk member configured to generate a substantially laminar flow or even flow of fluid in the direction of the substrate being plated. The exemplary plating cell 200 may be further described in commonly assigned U.S. patent application Ser. No. 10/268,284, which was filed on Oct. 9, 2002 under the title “Electrochemical Processing Cell”, which is incorporated herein by reference in its entirety.

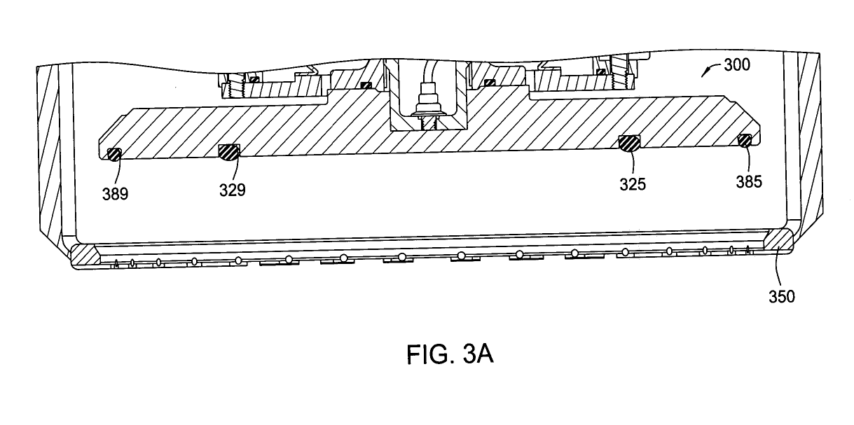

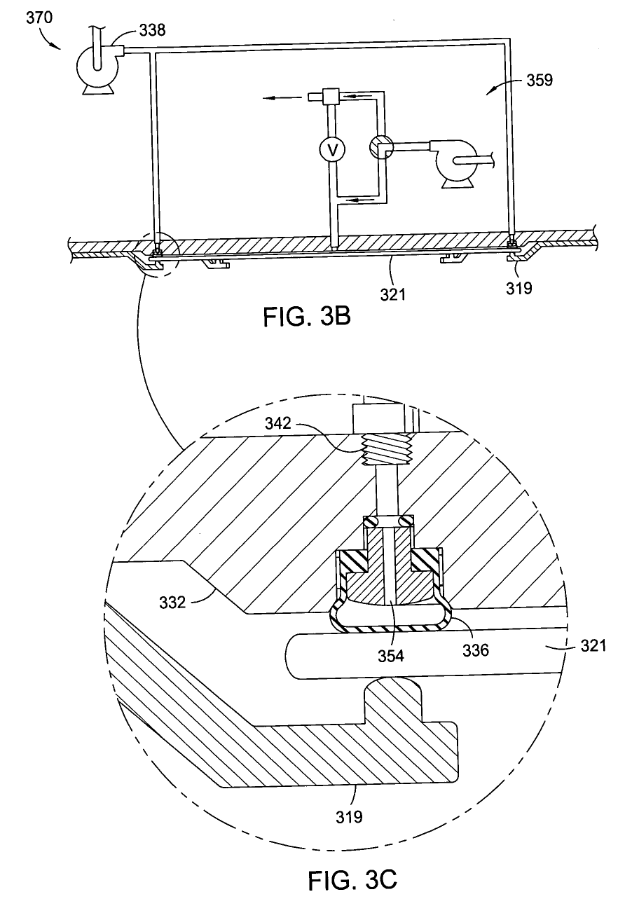

FIG. 3A illustrates an enlarged cross sectional view of a thrust plate 300 in accordance with one or more embodiments of the invention. The thrust plate 300 includes a first circular recess 389 and a first o-ring 385 disposed therein. The thrust plate 300 also includes a second circular recess 329 and a second o-ring 325 disposed therein. The diameter of the first o-ring 385 is substantially the same as the diameter of the substrate to be processed. The diameter of the second o-ring 325 is smaller than the diameter of the first o-ring 385. The thrust plate 300 is configured to press against the back side (i.e., non plating side) of the substrate such that the front side (i.e., the plating side) is pressed against a contact ring 350 during plating. As such, the second o-ring 325 is configured to press against a center region of the back side to bow or bend the substrate toward the front side. In one embodiment, for a 300 mm substrate, the second o-ring 325 is selected such that the center region of the substrate is bent from about 3 mm to about 5 mm from its original planar level, which typically coincides with a horizontal line connecting the bottom surface of the second o-ring 325. For a 300 mm substrate, the thickness of the second o-ring 325 may be 2 mm or greater than the first o-ring 385. The substrate may be bent during plating. The bending or bowing of the substrate is configured to compensate the tensile stress that the deposited layer experiences during annealing.

FIG. 3B illustrates a substrate holder having an inflatable bladder assembly 370 that may be used to bend the substrate during plating. The inflatable bladder assembly is configured to provide pressure against the back side of the substrate. The bladder inflatable assembly 370 includes a bladder 336 disposed on a lower surface of a substrate holder plate 332, as illustrated in FIG. 3C. The bladder 336 is disposed opposite to a contact ring 319 with a substrate 321 interposed therebetween. The bladder inflatable assembly 370 further includes a vacuum/pressure pumping system 359 configured to selectively supply a pressure or create a vacuum at a backside of the substrate 321. In operation, the substrate 321 may be secured to the lower side of the substrate holder plate 332 by engaging the pumping system 359 to evacuate the space between the substrate 321 and the substrate holder plate 332. The bladder 336 is then inflated by supplying a fluid such as air or water from a fluid source 338 to inlets 342. The fluid is delivered into the bladder 336 via manifold outlets 354, thereby pressing the substrate 321 uniformly against the contacts of the cathode contact ring 319.

Because of its flexibility, the bladder 336 deforms to accommodate the asperities of the substrate backside and contacts of the cathode contact ring 319, thereby mitigating misalignment with the conducting cathode contact ring 319. The compliant bladder 336 prevents the electrolyte from contaminating the backside of the substrate 321 by establishing a fluid tight seal at a perimeter portion of a backside of the substrate 321. Once inflated, a uniform pressure is delivered downward toward the cathode contact ring 319 to achieve substantially equal force at all points where the substrate 321 and cathode contact ring 319 interface. The force may be varied as a function of the pressure supplied by the fluid source 338.

In one embodiment, the bladder 336 may continued to be inflated until a center region of the substrate 321 is bent or bowed. For a 200 mm substrate, a backside pressure up to 5 psi may be used to bow the substrate, while for a 300 mm substrate, a backside pressure up to 10 psi may be used. Because substrates typically exhibit some measure of pliability, a backside pressure causes the substrate 321 to bow or assume a convex shape relative to the upward flow of the electrolyte. The degree of bowing may be varied according to the pressure supplied by the pumping system 359. In one embodiment, for a 300 mm substrate, the center region of the substrate may be bowed to a distance from about 2 mm to about 5 mm above a horizontal line connecting the periphery of the substrate. Other details of the inflatable bladder assembly 370 may be described in commonly assigned U.S. patent application Ser. No. 10/690,033 filed Oct. 20, 2003 under the title “Electro-chemical Deposition System”, which is incorporated herein by reference in its entirety.

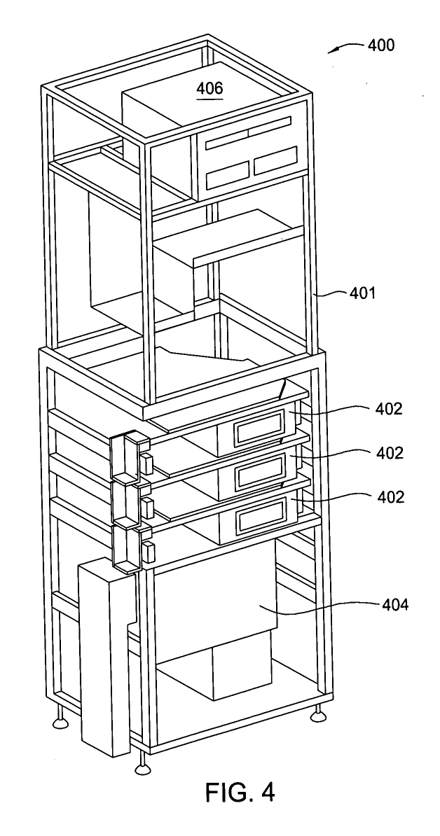

FIG. 4 illustrates a perspective view of an exemplary stacked annealing system 400 in accordance with one or more embodiments of the invention. The stacked annealing system 400 may be positioned at the annealing station 135 described in FIG. 1, or at another location on a processing platform, as desired. The annealing system 400 generally includes a frame 401 configured to support the various components of the annealing system 400. At least one annealing chamber 402 is positioned on the frame member 401 at a height that facilitates access thereto by a robot in the processing system, i.e., mainframe robot 120 or factory interface robot 132. In the illustrated embodiment, the annealing system 400 includes three (3) annealing chambers 402 stacked vertically on top of one another. However, embodiments of the invention are not intended to be limited to any particular number of annealing chambers or any particular spacing or orientation of the chambers relative to each other, as various spacing, numbers, and orientations may be implemented without departing from the scope of the invention.

The annealing system 400 may also include an electrical system controller 406 positioned on an upper portion of the frame member 401. The electrical system controller 406 generally operates to control the electrical power provided to the respective components of the annealing system 400, and in particular, the electrical system controller 406 operates to control the electrical power delivered to a heating element of the annealing chamber 402 so that the temperature of the annealing chamber may be controlled. The annealing system 400 may further include fluid and gas supply assembly 404 positioned on the frame member 401, generally below the annealing chambers 402. The fluid and gas supply assembly 404 may be configured to supply an annealing processing gas, such as nitrogen, argon, helium, hydrogen, or other inert gases that are amenable to semiconductor processing annealing, to the respective annealing chambers 402. Fluid and gas supply assembly 404 is also configured to supply and regulate fluids delivered to the annealing chamber 402, such as a cooling fluid used to cool the chamber body and/or annealed substrates after the heating portion of the annealing process is completed. The cooling fluid, for example, may be a chilled or cooled water supply. Supply assembly 404 may further include a vacuum system (not shown) that is individually in communication with the respective annealing chambers 402. The vacuum system may operate to remove ambient gases from the annealing chambers 402 prior to beginning the annealing process and may be used to support a reduced pressure annealing process. Therefore, the vacuum system allows for reduced pressure annealing processes to be conducted in the respective annealing chambers 402, and further, varying reduced pressures may be simultaneously used in the respective annealing chambers 402 without interfering with the adjoining chamber 402 in the stack.

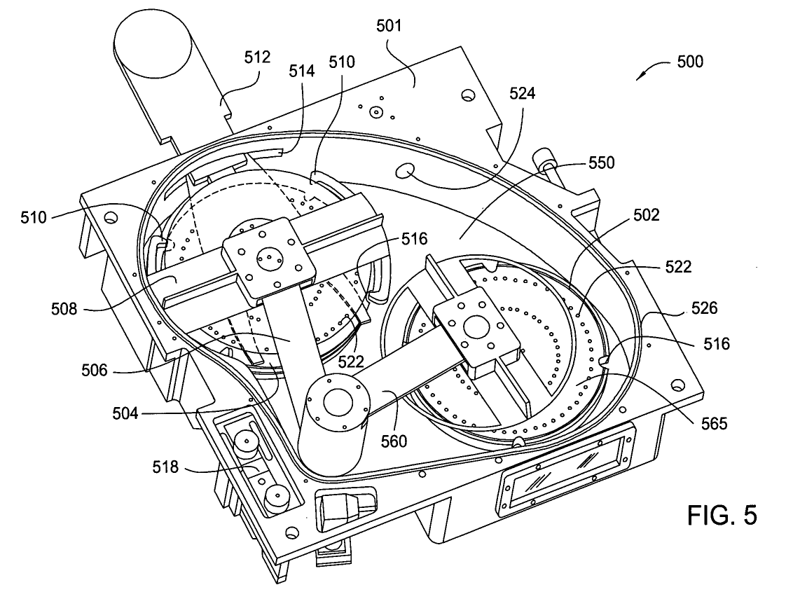

FIG. 5 illustrates a top perspective view of an annealing chamber 500 in accordance with one or more embodiments of the invention. FIG. 5 illustrates the annealing chamber 500 with the cover or lid portion of the chamber removed so that the internal components are visible. The annealing chamber 500 generally includes a chamber body 501 that defines an enclosed processing volume 550. The enclosed processing volume 550 includes a heating plate 502 and a cooling plate 504 positioned therein proximate each other. A substrate transfer mechanism 506 is positioned adjacent the heating and cooling plates and is configured to receive a substrate from outside the processing volume 550 and transfer the substrate between the respective heating and cooling plates during an annealing process. The substrate transfer mechanism 506 generally includes pivotally mounted robot assembly having a substrate support blade 508 positioned at a distal end of a pivotal arm of the robot. The blade 508 includes a plurality of substrate support tabs 510 that are spaced from the blade 508 and configured to cooperatively support a substrate thereon. Each of the support tabs 510 are generally spaced vertically (generally downward) from a main body portion 508 of the blade, which generates a vertical space between blade 508 and tabs 510. This spacing allows for a substrate to be positioned on the tabs 510 during a substrate loading process. Further, each of the heating and cooling plates 502, 504 include a corresponding number of notches 516 formed into the outer perimeter thereof, wherein the notches 516 are spaced and configured to cooperatively receive tabs 510 therein when the support blade 508 is lowered toward to the respective heating and cooling plates 502, 504.

The cooling plate 504 may include a substantially planar substrate support surface. In one embodiment, the cooling plate includes a curved substrate support surface. The substrate support surface includes a plurality of vacuum apertures 522, which are selectively in fluid communication with a vacuum source (not shown). The vacuum apertures 522 may be used to generate a reduced pressure at the substrate support surface to secure or vacuum chuck a substrate to the substrate support surface. The interior portion of the cooling plate 504 may include a plurality of fluid conduits formed therein, wherein the fluid conduits are in fluid communication with the cooling fluid source used to cool the chamber body 501. When the fluid conduits are implemented into the cooling plate 504, the cooling plate 504 may be used to rapidly cool a substrate positioned thereon. Alternatively, the cooling plate 504 may be manufactured without the cooling passages formed therein, and as such, the cooling plate 504 may be used to cool a substrate at a slower rate than the embodiment where the cooling plate 504 is essentially chilled by the cooling conduits formed therein. Further, as noted above, the cooling plate 504 includes a plurality of notches 516 formed into the perimeter of the plate 504, wherein the notches 516 are spaced to receive the tabs 510 of the substrate support blade 508 when the blade is lowered into a processing position.

The heating plate 502, in similar fashion to the cooling plate 504, may also include a substantially planar substrate support surface. In one embodiment, the heating plate 502 includes a curved substrate support surface. The substrate support surface includes a plurality a vacuum apertures 522 formed therein, each of the vacuum apertures 522 being selectively in fluid communication with a vacuum source (not shown). As such, the vacuum apertures 522 may be used to vacuum chuck or secure a substrate to the heating plate 502 for processing. The interior of the heating plate 502 includes a heating element (not shown), wherein the heating element is configured to heat the substrate support surface of the heating plate 502 to a temperature of between about 100° C. to about 500° C. The heating element may include, for example, an electrically driven resistive element or a hot fluid conduit formed into the heating plate 502. Alternatively, the annealing chambers may utilize an external heating device, such as lamps, inductive heaters, or resistive elements, positioned above or below the heating plate 502. Further, as noted above, the heating plate 502 includes a plurality of notches 516 formed into the perimeter of the plate 502, wherein the notches 516 are spaced to receive the tabs 510 of the substrate support blade 508 when the blade is lowered into a processing position. Additionally, one or more of the vacuum apertures 522 may also be in fluid communication with a heated gas supply, and as such, one or more of the apertures may be used to dispense a heated gas onto the backside of the substrate during processing. The heated gas, which may be heated to a temperature of between about 100° C. and 400° C., may be supplied from a plurality of apertures in fluid communication with the heated gas source, and then pumped from the backside of the substrate by other ones of the apertures 522 that are in fluid communication with the vacuum source noted above.

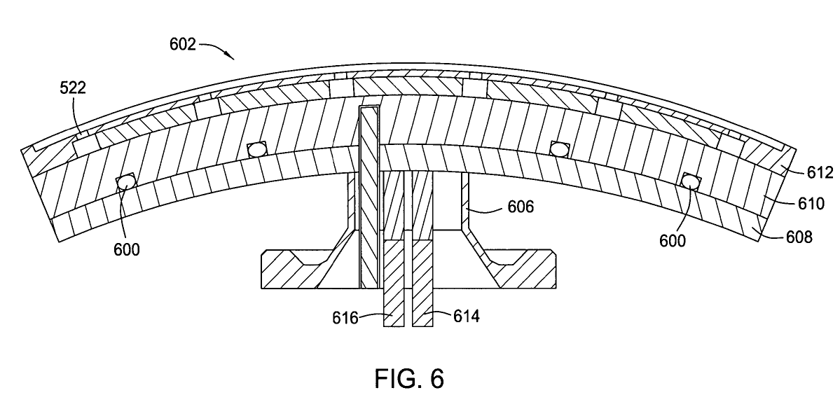

FIG. 6 illustrates a cross sectional view of a heating plate 602 in accordance with one or more embodiments of the invention. As briefly mentioned above, the heating plate 602 has a curved substrate support surface, rather than a planar or substantially flat surface. The curved surface is configured to bow a substrate disposed thereon during processing with the assistance of a substrate bowing mechanism 560, which will be discussed in more detail in the paragraphs below. The curved surface may be configured to bow a center region of a 300 mm substrate by about 2 mm to about 5 mm from the substrate's original planar axis.

The heating plate 602 may include a heating plate base member 608 that has a resistive heating element 600 positioned thereon. The resistive heating element 600 may be encased in the interior portion 610 of the heating plate 602. A top plate 612 is positioned above the interior portion 610. The top, interior, and base members are generally manufactured from a metal having desirable thermal conductivity properties, such as aluminum, for example. Additionally, the three sections of the plate 602 may be brazed together to form a unitary heat transferring plate 602. The lower portion of the plate 602, i.e., the bottom of the base member 608, may include a stem 606 that supports the plate 602. The stem is generally of a substantially smaller diameter than the plate member 602, which minimizes thermal transfer to the chamber base or walls. More particularly, the stem member generally has a diameter of less than about 20% of the diameter of the heating plate 602. Additionally, the lower portion of the stem 606 includes a thermocouple 614 for measuring the temperature of the heating plate 602 and a power connection 616 to conduct electrical power to the heating element 600.

Referring back to FIG. 5, the annealing chamber 500 may further include a substrate bowing mechanism 560 in accordance with one or more embodiments of the invention. The substrate bowing mechanism 560 is configured to press a substrate against the curved substrate support surface of the heating plate 502, while the substrate is being heated. The substrate bowing mechanism 560 may include a pressing ring 565, which is configured to press against the edge of the substrate in order to bend the substrate along the curved substrate support surface of the heating plate 502. In this manner, the substrate bowing mechanism 560 and the curved surface heating plate 602 may be used to bow the substrate while heating the substrate.

The annealing chamber 500 may further include a pump down aperture 524 positioned in fluid communication with the processing volume 550. The pump down aperture 524 is selectively in fluid communication with a vacuum source (not shown) and is generally configured to evacuate gases from the processing volume 550. Additionally, the annealing chamber generally includes at least one gas dispensing port 526 or gas dispensing showerhead positioned proximate the heating plate 502. The gas dispensing port is selectively in fluid communication with a processing gas source, i.e., supply source, and is therefore configured to dispense a processing gas into the processing volume 550. The gas dispensing port 526 may also be a gas showerhead assembly positioned in the interior of the annealing chamber. The pump down aperture 524 and the gas dispensing nozzle may be utilized cooperatively or separately to minimize ambient gas content in the annealing chamber, i.e., both of the components or one or the other of the components may be used.

The annealing chamber 500 may further include a substrate transfer mechanism actuator assembly 518 in communication with the substrate transfer mechanism 506. The actuator 518 is generally configured to control both pivotal movement of the blade 508, as well as the height or Z position of the blade relative to the heating or cooling member. An access door 514, which may be a slit valve-type door, for example, is generally positioned in an outer wall of the chamber body 501. The access door 514 is generally configured to open and allow access into the processing volume 550 of the annealing chamber 500. As such, access door 514 may be opened and a robot 512 (which may be robot 132 from the exemplary FI or the exemplary mainframe substrate transfer robot 120 illustrated in FIG. 1, for example) may enter into the processing volume 550 to drop off or retrieve a substrate from one of the annealing chambers 500.

More particularly, the process of inserting a substrate into the annealing chamber may include positioning the blade 508 over the cooling plate 504 in a loading position, i.e., a position where the tabs 510 are vertically positioned at a location above the upper surface of the cooling plate 504. The blade 508 and tabs 510 may be positioned relative to each other such that there is a vertical space between the upper surface of the tabs 510 and the lower surface of the blade 508. This vertical space is configured to allow a robot blade 512 having a substrate supported thereon to be inserted into the vertical space and then lowered such that the substrate is transferred from the blade 512 to the substrate support tabs 510. Once the substrate is supported by the tabs 510, the external robot blade 512 may be retracted from the processing volume 550 and the access door 514 may be closed to isolate the processing volume 550 from the ambient atmosphere.

Once the door 514 is closed, a vacuum source in communication with the pump down aperture 524 may be activated and caused to pump a portion of the gases from the processing volume 550. During the pumping process, or shortly thereafter, the gas dispensing port(s) 526 may be opened to allow the processing gas to flood the processing volume 550. The process gas is generally an inert gas that is known not to react under the annealing processing conditions. This configuration, i.e., the pump down and inert gas flooding process, is generally configured to remove as much of the oxygen from the annealing chamber/processing volume as possible, as the oxygen is known to cause oxidation to the substrate surface during the annealing process. The vacuum source may be terminated and the gas flow stopped when the chamber reaches a predetermined pressure and gas concentration, or alternatively, the vacuum source may remain activated during the annealing process and the gas delivery nozzle may continue to flow the processing gas into the processing volume.

Once the substrate is positioned on the support blade 508, the substrate may be lowered onto the cooling plate 504 or heating plate 502. The process of lowering the substrate onto either the heating plate 502 or the cooling plate 504 generally includes positioning the support blade 508 above the respective plate such that the substrate support tabs 510 are positioned above the notches 516 formed into the perimeter of the plates. The support blade 508 may then be lowered such that the tabs 510 are received in the notches 516. As the substrate support tabs 510 are received in the notches 516, the substrate supported on the tabs 510 is transferred to the upper surface of the respective heating or cooling plate.

The transfer process generally includes activating the vacuum apertures 522 formed into the plate upper surfaces, so that a substrate is secured to the surface without movement when placed thereon. The heating plate is generally heated to a predetermined annealing temperature, such as between about 150° C. and about 400° C. or 450° C., before the substrate is positioned thereon. Alternative temperature ranges for the heating plate include between about 150° C. and about 250° C., between about 150° C. and about 325° C., and between about 200° C. and about 350° C., for example. The substrate is positioned on the heating plate 502 (generally vacuum chucked thereto) for a predetermined period of time and annealed, generally between about 15 seconds and about 120 seconds, for example, depending on the desired annealing temperature and the time required to generate the desired structure in the layer deposited on the substrate.

In high temperature annealing processes, i.e., annealing processes where the annealing temperature (the temperature of the heating plate 502) is high enough to thermally shock and possibly damage the substrate, a temperature ramping process may be implemented. As such, the heating plate 502 may be maintained at a first temperature and the substrate may be positioned on the heating plate 502. The first temperature is calculated to begin the annealing process without damaging or shocking the substrate. Once the substrate is positioned on the heating plate, the temperature of the plate may be increased to a second temperature, wherein the second temperature is greater than the first temperature. In this configuration, the substrate temperature increases from the first temperature to the second temperature at a rate that is calculated not to damage or shock the substrate.

The heating plate 502 may also be heated to the annealing temperature. However, the annealing process begins with the substrate being positioned immediately above the heating plate 502, e.g., an air space or gap is left between the substrate and the upper surface of the heating plate 502. During the time period while the substrate is positioned above the heating plate, i.e., hovered above the plate, heat is transferred from the plate 502 to the substrate, thus heating the substrate. Once the substrate temperature is increased to a temperature where thermal damage or shock may be prevented, then the substrate is lowered onto the heating plate 502, i.e., into direct contact with the heating plate. This configuration allows for temperature ramping of the substrate without having to control the heating mechanism of the heating plate 502.

Once the heating portion of the annealing process is completed, the substrate may be transferred to the cooling plate 504. The transfer process includes terminating the vacuum chucking operation and lifting the support blade 508 upward until the tabs 510 engage and support the substrate thereon, i.e., wherein the tabs 510 lift the substrate off of the heating plate surface. The support blade 508 may then be pivoted from the heating plate 502 to the cooling plate 504. Once above the cooling plate 504, blade 508 may be lowered to position the substrate onto the cooling plate 504. In similar fashion to the lowering process described below, the substrate may be lowered onto the cooling plate while the vacuum apertures 522 are simultaneously operating to secure the substrate to the upper surface of the cooling plate 504.

The cooling plate may generally be maintained at a reduced temperature, such as between about 15° C. and about 40° C., and therefore, the cooling plate operates to receive or sink heat from the substrate positioned thereon or proximate thereto. This process may be used to cool the substrate from the annealing temperature down to less than about 70° C., or more particularly, between about 50° C. and about 100° C. in less than 1 minute, or more particularly, in less than about 15 seconds. More particularly, the cooling plate may be used to rapidly cool the substrate to between about 50° C. and about 70° C. in less than about 12 seconds. Once the substrate is cooled to the desired temperature, the blade 508 may be used to raise the substrate off of the cooling plate 504. With the substrate raised, the door 514 may be opened and the outside robot blade 512 may be brought into the processing volume and used to remove the substrate from the support blade 508. Once the substrate is removed, another substrate may be positioned in the annealing chamber and the annealing process described above may be repeated.

The annealing chamber 500 and various processes used therein may be further described in commonly assigned U.S. patent application Ser. No. 10/823,849, filed Apr. 13, 2004 under the title “Two Position Anneal Chamber”, which is incorporated herein by reference in its entirety.

While the foregoing is directed to embodiments of the present invention, other and further embodiments of the invention may be devised without departing from the basic scope thereof, and the scope thereof is determined by the claims that follow.

What is claimed is:

1. A method for compensating for tensile stress on a layer deposited on a substrate, comprising:
disposing the substrate between a bladder and a contact ring; and
applying pressure against a back side of the substrate toward the contact ring to bend a center region of the substrate until the substrate assumes a convex shape relative to an upward flow of a plating solution.

2. The method of claim 1, wherein the substrate has a diameter of about 300 mm and the pressure is applied until the center region of the substrate is bent about 3 mm to about 5 mm relative to a horizontal line connecting the periphery of the substrate.

3. The method of claim 1, wherein the center region of the substrate is bent during plating.

4. A method for compensating for tensile stress on a film deposited on a substrate, comprising:
providing a thrust plate having a bottom surface defining a first circular recess for containing a first o-ring and a second circular recess for containing a second o-ring, wherein the diameter of the first o-ring is substantially larger than the diameter of the second o-ring and the diameter of the first o-ring substantially coincides with the diameter of the substrate;
disposing the substrate between the thrust plate and a contact ring; and
applying pressure against a back side of the substrate toward the contact ring to bend a center region of the substrate.

5. The method of claim 4, wherein the center region of the substrate is bent during plating.

6. The method of claim 4, wherein the substrate has a diameter of about 300 mm and the center region is bent about 3 mm to about 5 mm relative to a horizontal line connecting a bottom surface of the second o-ring.

7. The method of claim 4, wherein the second o-ring is thicker than the first o-ring.

8. A thrust plate for retaining a substrate, comprising:
a first o-ring for biasing a back side of the substrate against a contact ring, wherein the first o-ring has a diameter substantially the same as the diameter of the substrate; and
a second o-ring for bending a center region of the substrate, wherein the second o-ring has a diameter less than the first o-ring.

9. The thrust plate of claim 8, wherein the thickness of the second o-ring is greater than the thickness of the first o-ring.

10. The thrust plate of claim 8, wherein the second o-ring is thicker than the first o-ring by about 2 mm or greater.

11. The thrust plate of claim 10, wherein the substrate has a diameter of about 300 mm.

12. A method for annealing a substrate, comprising:
positioning the substrate on a heating plate for a first predetermined period of time, wherein the heating plate comprises a curved substrate support surface and the heating plate is maintained at a temperature of between about 200° C. and 400° C.; and
pressing the substrate against the curved substrate support surface.

13. The method of claim 12, wherein the substrate is pressed against the curved surface to bend a center region of the substrate.

14. The method of claim 12, wherein the substrate is pressed against the curved surface by a substrate bowing mechanism.

15. The method of claim 12, wherein pressing the substrate comprises pressing the periphery of the substrate against the curved surface of the hot plate.

16. The method of claim 12, further comprising positioning the substrate on a cooling plate for a second predetermined period of time, the cooling plate being configured to cool the substrate to a temperature of between about 50° C. and 100° C. in less than about 30 seconds.

17. The method of claim 12, wherein the substrate has a diameter of about 300 mm.

18. An annealing chamber, comprising:
a heating plate having a first curved substrate support surface;
a cooling plate having a second curved substrate support surface; and
a substrate transfer mechanism configured to transfer one or more substrates between the heating plate and the cooling plate.

19. The annealing chamber of claim 18, further comprising a substrate bowing mechanism configured to press the one or more substrates against the curved substrate support surface of the heating plate.

20. The annealing chamber of claim 19, wherein the substrate bowing mechanism is further configured to press the one or more substrates against the curved substrate support surface of the cooling plate.
